(19) United States
(12) Patent Application Publication
(10) Pub. No.: US 2026/0287693 A1
(43) Pub. Date: Sep. 24, 2026

(54) MAGNETIC RESONANCE IMAGING APPARATUS

(71) Applicant: CANON KABUSHIKI KAISHA, Tokyo (JP)

(72) Inventors: Gaku KANEDA, Utsunomiya Tochigi (JP); Yuto ONO, Nasushiobara Tochigi (JP); Nami FUJIMOTO, Nasushiobara Tochigi (JP); Hidetaka KONTA, Utsunomiya Tochigi (JP); Yoshihito ABE, Utsunomiya Tochigi (JP); Ryuji MICHIZOE, Utsunomiya Tochigi (JP)

(73) Assignee: CANON KABUSHIKI KAISHA, Tokyo (JP)

(21) Appl. No.: 19/539,212

(22) Filed: Feb. 13, 2026

(30) Foreign Application Priority Data
Mar. 21, 2025 (JP) 2025-046928

(51) Int. Cl. G01R 33/3415; G01R 33/38; G01R 33/56

(52) U.S. Cl. CPC G01R 33/3415; G01R 33/3806; G01R 33/5608

(57) ABSTRACT

According to one embodiment, a magnetic resonance imaging apparatus includes a gantry apparatus, a supporting portion, a receiver coil, and a moving controller. The supporting portion rotatably supports the gantry apparatus relative to the supporting portion between a first position and a second position, the subject on a couchtop being scanned in a first state where the gantry apparatus is located at the first position before the subject on the couchtop is scanned in a second state where the gantry apparatus is located at the second position. The moving controller, in a case where the subject is scanned in the second state, moves at least one of the couchtop and the receiver coil so that a difference between a position of an examination target portion of the subject in the first state and a position of the examination target portion of the subject in the second state is reduced.

### CROSS-REFERENCE TO RELATED APPLICATIONS

This application is based upon and claims the benefit of priority from Japanese Patent Application No. 2025-046928, filed Mar. 21, 2025, the entire contents of which are incorporated herein by reference.

### FIELD

Embodiments described herein relate generally to a magnetic resonance imaging (MRI) apparatus.

### BACKGROUND

An MRI apparatus is an imaging apparatus that performs a scan in which nuclear spins of a subject placed in a static magnetic field are excited by a radio frequency (RF) pulse at the Larmor frequency, and magnetic resonance (MR) signals generated from the subject in association with the excitation are collected. An MR image is then generated based on the MR signals collected through the scan.

There are MRI apparatuses capable of imaging a patient who serves as a subject, before and after a change in body position between a lying position and a standing position. In such an MRI apparatus, imaging can be performed in both the supine position and the standing position without the patient moving, and therefore the apparatus is considered useful for examinations and diagnoses of diseases related to, for example, nephroptosis, floating kidney, and gastroptosis. However, when the body position changes between the supine position and the standing position, the position of the examination target portion of the subject may shift, making it difficult to image the examination target portion after the change of the body position, or requiring position adjustment by a user such as a technician.

### BRIEF DESCRIPTION OF THE DRAWINGS

FIG. 1 is a block diagram illustrating an example of an overall configuration of a magnetic resonance imaging (MRI) apparatus according to a first embodiment;

FIGS. 2A and 2B are explanatory diagrams regarding a change in body position between a supine position and a standing position;

FIGS. 3A and 3B are diagrams illustrating a change in position of an examination target portion of a subject between the supine position and the standing position;

FIG. 4 is a flowchart illustrating an example of an operation of the MRI apparatus according to the first embodiment;

FIGS. 5A and 5B are explanatory diagrams regarding an amount of positional change of the examination target portion before and after a change in body position;

FIGS. 6A and 6B are explanatory diagrams regarding an amount of adjustment for a position of a couchtop and an amount of adjustment for a position of a receiver coil;

FIG. 7 is an explanatory diagram regarding movement of the couchtop and the receiver coil;

FIGS. 8A and 8B are explanatory diagrams regarding a change in body position between a supine position and a sitting position;

FIG. 9 is a block diagram illustrating an example of processing circuitry of an MRI apparatus according to a second embodiment;

FIG. 10 a flowchart illustrating an example of an operation of the MRI apparatus according to the second embodiment;

FIG. 11 is a block diagram illustrating an example of processing circuitry of an MRI apparatus according to a third embodiment;

FIG. 12 a flowchart illustrating an example of an operation of the MRI apparatus according to the third embodiment; and

FIGS. 13A and 13B are explanatory diagrams regarding movement of the couchtop and identification of an element coil.

### DETAILED DESCRIPTION

According to one embodiment, a magnetic resonance imaging (MRI) apparatus includes a gantry apparatus, a supporting portion, a receiver coil, and a moving controller. The gantry apparatus includes a static magnetic field magnet that generates a static magnetic field and a couchtop on which a subject is placed. The supporting portion rotatably supports the gantry apparatus relative to the supporting portion between a first position and a second position, the subject on the couchtop being scanned in a first state where the gantry apparatus is located at the first position before the subject on the couchtop is scanned in a second state where the gantry apparatus is located at the second position. The receiver coil detects magnetic resonance (MR) signals from the subject. The moving controller, in a case where the subject is scanned in the second state, moves at least one of the couchtop and the receiver coil in a longitudinal direction of the couchtop so that a difference between a position of an examination target portion of the subject in the first state and a position of the examination target portion of the subject in the second state is reduced.

Various Embodiments will be described hereinafter with reference to the accompanying drawings. In each drawing, identical elements are denoted by the same reference numerals, and redundant descriptions are omitted.

### (Overall Configuration of MRI Apparatus)

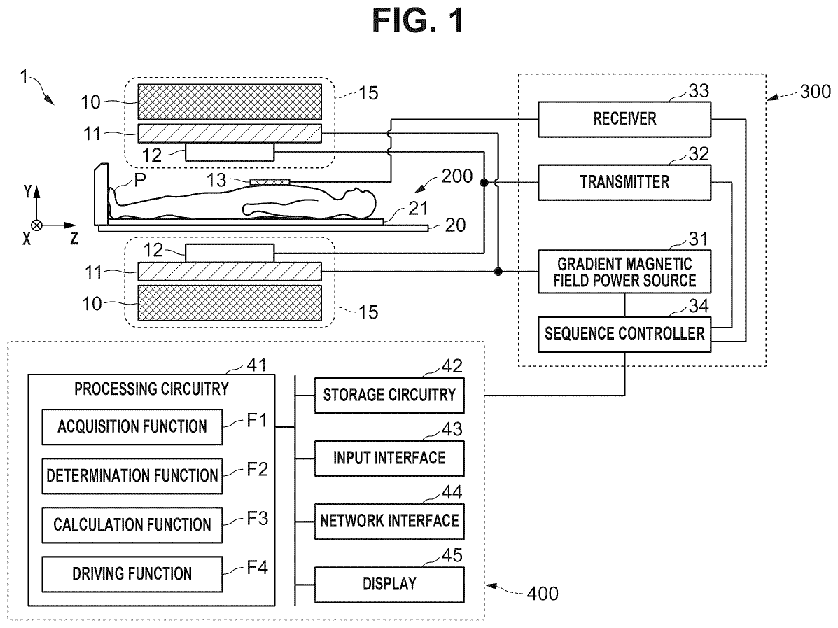

FIG. 1 is a block diagram illustrating an example of an overall configuration of an MRI apparatus 1 according to an embodiment. The MRI apparatus 1 includes a gantry apparatus 100, a control cabinet 300, and an image processing apparatus 400. Part or the whole of the image processing apparatus 400 may be installed at a remote location and connected to the MRI apparatus 1 via a network.

Here, a Z-axis direction is defined as a direction that is set along a magnetic flux from a static magnetic field generated by a static magnetic field magnet 10 and that is the same direction as the longitudinal direction of a couchtop 21. A Y-axis direction is defined as a vertical direction orthogonal to the Z-axis direction and is a direction perpendicular to the couchtop 21. An X-axis direction is defined as a direction that is orthogonal to both the Z-axis direction and the Y-axis direction and that is the same direction as the lateral direction of the couchtop 21.

The gantry apparatus 100 includes the static magnetic field magnet 10, a gradient magnetic field coil 11, a transmission coil 12, a receiver coil 13, and a couch 200. The gantry apparatus 100 of the MRI apparatus 1 may be a plane open type configured to capture an image of a subject P in an examination space sandwiched by two plate-shaped static magnetic field magnets 10, or may be a cylinder type configured to capture an image of the subject P in an examination space surrounded by a substantially cylindrical static magnetic field magnet.

In the gantry apparatus 100 of the plane open type, a plate-shaped gradient magnetic field coil 11 and a plate-shaped transmission coil 12 are arranged on the examination space side of each of the two plate-shaped static magnetic field magnets 10, and are accommodated in a gantry housing 15. In the gantry apparatus of the cylinder type, a substantially cylindrical gradient magnetic field coil and a substantially cylindrical transmission coil are arranged on the examination space side of the substantially cylindrical static magnetic field magnet, and are accommodated in a gantry housing.

The static magnetic field magnet 10 generates a static magnetic field in an examination space (that is, inside a bore) into which a patient as the subject P is carried. The static magnetic field magnet 10 incorporates a superconducting coil, which is cooled to an extremely low temperature by liquid helium. The static magnetic field magnet 10 generates a static magnetic field by applying a current supplied from a static magnetic field power source (not illustrated) to the superconducting coil in an excitation mode. Thereafter, when the static magnetic field magnet 10 transitions to a persistent current mode, the static magnetic field power supply is disconnected. Once the static magnetic field magnet 10 transitions to the persistent current mode, it continues to generate a strong static magnetic field for a long period of time, for example, more than one year.

The static magnetic field magnet 10 may be a magnet employing a conduction cooling method in which a refrigerator and a superconducting coil are brought into thermal contact to cool the superconducting coil. In this case, liquid helium or another coolant may not be used, or several liters of liquid helium or another coolant may be used. The static magnetic field magnet 10 may also be a superconducting magnet immersed in liquid helium or another coolant, or may be of a thermosiphon type that cools the superconducting coil by circulating coolant through a tube. The static magnetic field magnet 10 may alternatively be configured as a permanent magnet.

The gradient magnetic field coil 11 is fixed inside the static magnetic field magnet 10. The gradient magnetic field coil 11 generates a gradient magnetic field by receiving a supply of current from a gradient magnetic field power source 31. Specifically, Specifically, the gradient magnetic field coil 11 incorporates coils that generate respective magnetic fields corresponding to an X-axis, a Y-axis, and a Z-axis, which are orthogonal to one another. coils corresponding to the respective axes receives a supply of current individually from the gradient magnetic field power source 31, and generate respective gradient magnetic fields corresponding to the X-axis, the Y-axis, and the Z-axis.

The transmission coil 12 transmits a radio frequency (RF) pulse transmitted from the transmitter 32 to the subject P to excite the subject P. The transmission coil 12 is fixed, for example, inside the gradient magnetic field coil 11.

The receiver coil 13 detects MR signals emitted from the subject P by excitation with the RF pulse. The receiver coil 13 is a coil device in which one or more element coils are stored in a housing. The receiver coil 13 is disposed, for example, in proximity to the subject P. The receiver coil 13 may be of various types that maintain a fixed shape according to the imaging portion of the subject P, such as the head, the chest, the abdomen (for example, refer to FIG. 1), the spine, the lower limbs, or the whole body.

The receiver coil 13 may be a phased-array coil configured by combining a plurality of surface coils as element coils. The receiver coil 13 may also be of a highly flexible type that is deformable and has a high degree of freedom in arrangement, including so-called wearable type coils. The receiver coil 13 is, for example, deformable into a desired shape according to the body position, body shape, or the like imaging portion of the subject P, and can be wrapped around the subject P. Either the front surface or the back surface can be placed in contact with the subject and installed in any orientation.

In a case where the receiver coil 13 is configured with a plurality of multiple element coils, for example, one or a plurality of element coils disposed at positions at which MR signals from the examination target portion of the subject P can be obtained with sufficient receiver sensitivity may be identified as element coils effective for diagnostic scan, and MR signals from the identified element coils may be selectively detected to acquire MR images with good image quality.

The control cabinet 300 includes the gradient magnetic field power source 31, a transmitter 32, a receiver 33, and a sequence controller 34.

Under control of the sequence controller 34, the gradient magnetic field power source 31 supplies current to the gradient magnetic field coil 11, and causes the gradient magnetic field coil 11 to generate gradient magnetic fields along the X-axis, the Y-axis, and the Z-axis.

Based on an instruction from the sequence controller 34, the transmitter 32 generates an RF pulse sequence in the Larmor frequency band as an RF transmission wave and outputs it to the transmission coil 12.

The receiver 33 performs analog to digital (AD) conversion of the MR signal received by the receiver coil 13 and outputs it to the sequence controller 34. The digitized MR signal is referred to as raw data.

Under control of the image processing apparatus 400, the sequence controller 34 drives the gradient magnetic field power source 31, the transmitter 32, and the receiver 33 to execute a scan of the subject P. The sequence controller 34 receives raw data from the receiver 33 through execution of the scan, and transmits the raw data to the image processing apparatus 400.

The sequence controller 34 includes processing circuitry (not illustrated). The processing circuitry is configured with hardware such as a processor that executes a predetermined program, a field programmable gate array (FPGA) or an application specific integrated circuit (ASIC).

The couch 200 includes a couch main body 20, a couchtop 21, and a couch control device. On the couchtop 21, the subject P to be carried into the static magnetic field is placed. The couch main body 20 includes a couchtop support portion 20a and a supporting portion 20b. The couchtop support portion 20a supports the couchtop 21. The supporting portion 20b is installed on the floor surface, and supports the couchtop support portion 20a as a column portion. That is the supporting portion 20b rotatably supports the gantry apparatus 100 relative to the supporting portion 20b between a first position and a second position. Note that both the first position and the second position include the supine position, the standing position, and the sitting position, wherein a posture of the subject P corresponds to the position of the subject P. Under control of the image processing apparatus 400, the couch control device moves the couchtop 21 in in the vertical direction and the horizontal direction.

The image processing apparatus 400 includes processing circuitry 41, storage circuitry 42, an input interface 43, a network interface 44, and a display 45. The image processing apparatus 400 is configured by, for example, a computer.

The processing circuitry 41 is circuitry including, for example, a central processing unit (CPU) or a dedicated or general-purpose processor. The processor in the processing circuitry 41 implements various functions F1-F6 corresponding to various programs by executing programs that are stored in advance in the storage circuitry 42 or directly incorporated into the processing circuitry 41. A part of or all of the various functions F1-F6 may be realized by the moving controller (not illustrated) including processing circuitry installed on the gantry apparatus 100 or the couch 200.

The storage circuitry 42 is a storage medium including, a read only memory (ROM) and a random access memory (RAM), as well as an external storage device such as a hard disk drive (HDD) or an optical disk device. The storage circuitry 42 stores various types of information and data, and stores various types of programs executed by the processor of the processing circuitry 41.

An input interface 43 includes various types of input devices for a user to input various types of information and data, and input circuitry that processes signals from the input devices. The input devices includes, for example, a mouse, a keyboard, a trackball, a touch panel, a non-contact input device using an optical sensor, or a voice input device. When an input device is operated, the input circuitry generates an instruction signal corresponding to the operation and outputs the instruction signal to the processing circuitry 41.

The network interface 44 communicates with various devices connected to the network in a wired or wireless manner, and exchanges various types of information and data.

A display 45 is a display device such as a liquid crystal display panel, a plasma display panel, or an organic electroluminescent (EL) panel. The display 45 displays various types of information and data under the control of the processing circuit 41, and may also be a graphic user interface (GUI) that functions as an input device.

By these components, the image processing apparatus 400 controls the entire MRI apparatus 1. Specifically, the processing circuitry 41 receives instructions regarding imaging conditions or other various information through operations performed via the input interface 43 by a user such as a radiologic technologist. The processing circuitry 41 then causes the sequence controller 34 to execute scanning based on the input imaging conditions. In addition, the processing circuitry 41 reconstructs an MR image based on the raw data transmitted from the sequence controller 34. The reconstructed MR image is displayed on the display 45 and stored in the storage circuitry 42.

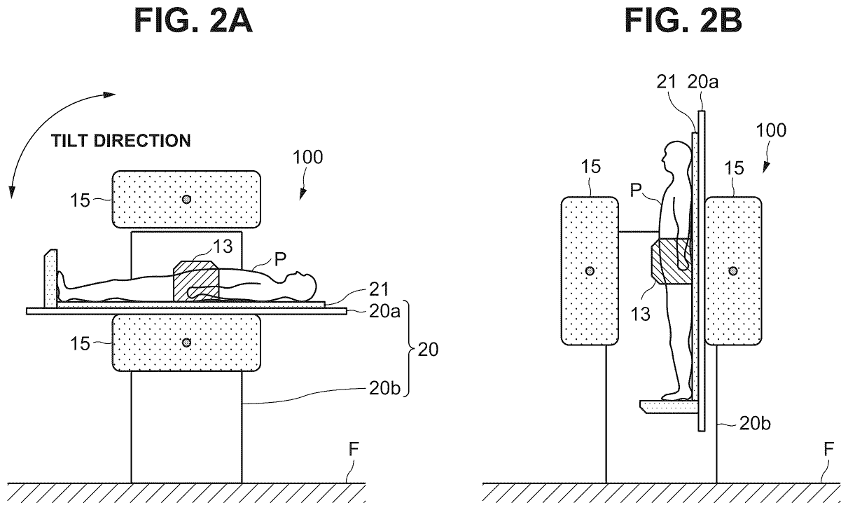

Here, FIGS. 2A and 2B are explanatory diagrams regarding a change in body position of the subject P. The gantry apparatus 100 of the MRI apparatus 1 according to the embodiment is rotatable in a tilt direction so that the subject P can be imaged before and after a change in body position between a supine position and a standing position. Here, the tilt direction refers to a rotational direction about the X-axis (that is, an axis parallel to the short-side direction of the couchtop 21). The X-axis that passes through the magnetic field center (that is, the iso center) of the static magnetic field magnet 10 may also serve as the rotation axis. As the gantry apparatus 100 rotates in the tilt direction, the subject P in the supine position in FIG. 2A is brought into the standing position in FIG. 2B.

In this manner, the MRI apparatus 1 allows imaging in both the supine position and the standing position without requiring the patient to move, and is therefore considered useful for examinations and diagnoses of diseases related to, for example, nephroptosis, floating kidney, and gastroptosis.

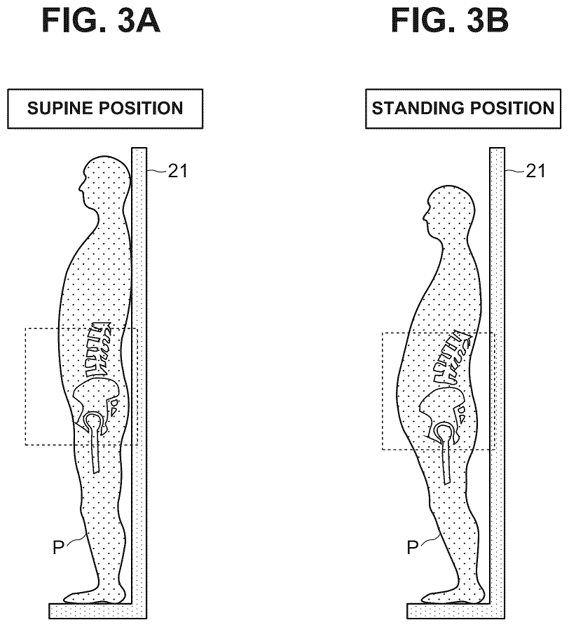

However, with a change in body position between the supine position and the standing position, the position of the examination target portion of the subject P changes relative to the static magnetic field magnet 10. FIGS. 3A and 3B are diagrams illustrating examples of positional changes of the examination target portion of the subject P in the supine position and the standing position. With the change in body position of the subject P, for example, the positions of the examination target portions such as the chest, the abdomen, and the pelvis changes. The change in position of the examination target portion includes changes in position of predetermined organs such as the heart, the liver, the stomach, the intestines, the pancreas, the spleen, the gallbladder, and the urinary organs.

Therefore, in order to image the examination target portion of the subject P after a change in body position, it may be necessary for a user such as a technician to adjust the imaging position. However, adjustment of the imaging position by the user may not be performed with high accuracy depending on the level of experience of the user, and the complexity of the operation may lead to a decrease in examination efficiency. Accordingly, the MRI apparatus 1 according to the embodiment enables appropriate imaging of the examination target portion of the subject P after the change in body position by automatically moving at least one of the couchtop 21 and the receiver coil 13 based on the amount of positional change of the examination target portion of the subject P before and after the change in body position.

### First Embodiment

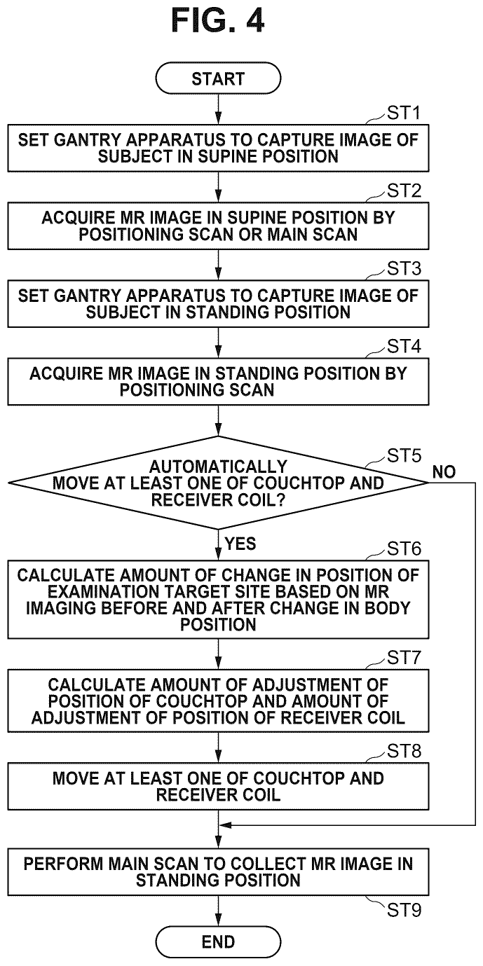

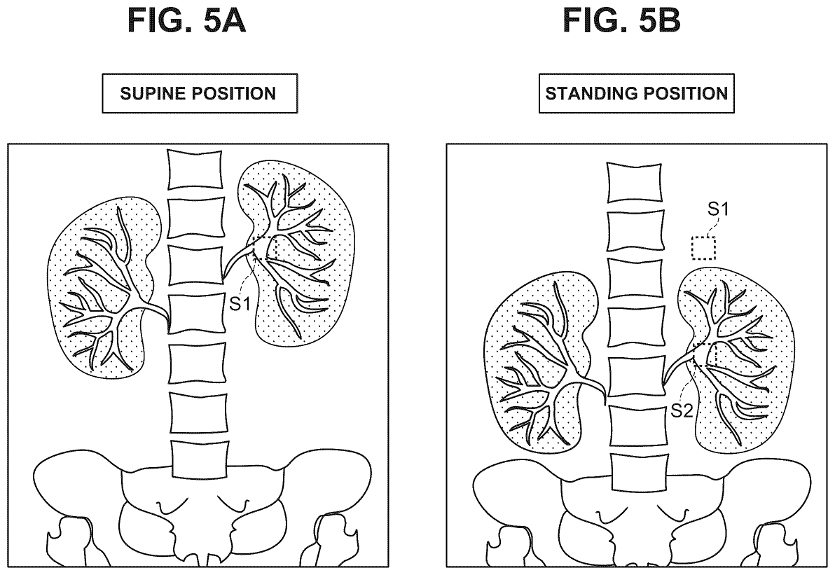

FIG. 1 is also a diagram illustrating an example of the processing circuitry 41 of the MRI apparatus 1 according to the first embodiment. In the first embodiment, the processing circuitry 41 executes an acquisition function F1, a determination function F2, a calculation function F3, and a driving function F4. Hereinafter, examples of operations of these functions in the MRI apparatus 1 according to the first embodiment will be described below with reference to a flowchart in FIG. 4, and FIGS. 5A to 7. The following description will be given of a case where the MRI apparatus 1 sets the gantry apparatus 100 so that the subject P is imaged after a change in body position from the supine position to the standing position. However, the MRI apparatus 1 may also set the gantry apparatus 100 so that the subject P is imaged after a change in body position from the standing position to the supine position.

In step ST1, the MRI apparatus 1 sets the gantry apparatus 100 so as to image the subject P in the supine position before and after the change in body position between the supine position and the standing position. The MRI apparatus 1 holds the gantry apparatus 100 at a predetermined tilt angle. Here, it is desirable that the position of the examination target portion of the subject P is set so as to approach the center of the magnetic field of the static magnetic field magnet 10, that is, substantially at the center of the field of view (FOV).

In step ST2, the acquisition function F1 acquires an MR image in the supine position, which is collected by a positioning scan or a main scan performed by the MRI apparatus 1. The main scan refers to a scan for obtaining a diagnostic image. The positioning scan refers to a scan executed before the main scan for obtaining an image to be used for positioning in the main scan.

In step ST3, the MRI apparatus 1 sets the gantry apparatus 100 so as to image the subject P in the standing position before and after the change in body position between the supine position and the standing position. The MRI apparatus 1 rotates the gantry apparatus 100 to hold the gantry apparatus 100 at a predetermined tilt angle.

In advance, the burden on the subject P caused by the change in body position may be forcibly or assistively reduced by fixing joint portions with bands or the like, or by supporting the body with auxiliary tools, and the posture of the subject P may be prevented from changing significantly before and after the change in body position. Additionally, in a case where the posture of the subject P changes significantly after the change in body position, improvement of the posture (for example, an action to straighten a bent joint portion) may be encouraged.

In step ST4, the acquisition function F1 acquires an MR image in the standing position, which is collected by a positioning scan performed by the MRI apparatus 1.

In step ST5, the determination function F2 determines whether to automatically move at least one of the couchtop 21 and the receiver coil 13. In a case where a predetermined range of the examination target portion is not included in an imaging region (that is, not included in the FOV), the determination function F2 may determine to automatically move at least one of the couchtop 21 and the receiver coil 13. For example, in a case where substantially the entire predetermined organ, such as the heart, the liver, the stomach, the intestines, the pancreas, the spleen, the gallbladder, or the urinary organs, as the examination target portion is not included within a predetermined range (for example, within a 50% range of the entire FOV from the center of the FOV), the determination function F2 may determine to automatically move at least one of the couchtop 21 and the receiver coil 13.

The determination function F2 may determine whether to move at least one of the couchtop 21 and the receiver coil 13 based on input information input by the user regarding automatic movement of the couchtop 21 and the receiver coil 13. For example, a setting screen related to whether to perform automatic movement of the couchtop 21 and the receiver coil 13 may be output to the display 45, and the user may input information related to automatic movement via the input interface 43 in accordance with the setting screen.

In a case where the position of the examination target portion changes before and after the change in body position, the determination function F2 may determine to automatically move at least one of the couchtop 21 and the receiver coil 13. For example, in a case where a region such as the chest, the abdomen, or the pelvis or a predetermined organ such as the heart, the liver, the stomach, the intestines, the pancreas, the spleen, the gallbladder, or the urinary organs is set as an imaging target portion, it is assumed that the position of the examination target portion will change before and after the change in body position, so that the determination function F2 may determine to automatically move at least one of the couchtop 21 and the receiver coil 13.

In a case where the determination function F2 determines to automatically move at least one of the couchtop 21 and the receiver coil 13 in step SST5 (that is, YES in step ST5), the processing proceeds to step ST6. In contrast, in a case where the determination function F2 determines not to automatically move at least one of the couchtop 21 and the receiver coil 13 (that is, NO in step ST5), the processing proceeds to step ST9. The processing may proceed from step ST4 to ST6 without execution of the processing in step ST5 on the premise that automatic movement is performed in advance.

In step ST6, the calculation function F3 calculates the amount of positional change between the position of the examination target portion of the subject P before the change in body position and the position of the examination target portion of the subject P after the change in body position. In the first embodiment, the amount of change is calculated based on the MR images acquired in steps ST2 and ST4. That is, the calculation function F3 calculates the amount of change based on the MR image of the subject P before the change in body position and the MR image of the subject P after the change in body position.

Here, FIG. 5A illustrates an example of an MR image of the subject P in the supine position before the change in body position. FIG. 5B illustrates an example of an MR image of the subject P in the standing position after the change in body position. FIGS. 5A and 5B illustrate how the position of the kidney, which is the examination target portion, changes before and after the change in body position. In FIG. 5B, an anatomical feature point of the kidney, which has been depicted at a position S1 within the FOV in the supine position, is depicted at a position S2 within the FOV in the standing position. In this case, the amount of change in position of the kidney before and after the change in body position is the difference between the position S1 and the position S2. The anatomical feature point is not limited to a single point, and there may be a plurality of anatomical feature points, or there may be a region.

The calculation function F3 may calculate the amount of change between the position of the examination target portion of the subject P before the change in body position and the position of the examination target portion of the subject P after the change in body position by comparing the anatomical feature points of the examination target portion before and after the change in body position.

The calculation function F3 may calculate the amount of positional change using an image recognition technique based on artificial intelligence (AI). For example, the calculation function F3 may identify the examination target portion and an anatomical feature point of the examination target portion using an AI-based image recognition technique such as segmentation, and calculate the amount of positional change between the position of the examination target portion of the subject P before the change in body position and the position of the examination target portion of the subject P after the change in body position. In this case, an image registration technique may also be used in combination before and after the change in body position.

In step ST7, the calculation function F3 calculates an amount of adjustment L1 for the position of the couchtop 21 and an amount of adjustment L2 for the position of the receiver coil 13 based on the amount of positional change between the position of the examination target portion of the subject P before the change in body position and the position of the examination target portion of the subject P after the change in body position, so that the position of the examination target portion after the change in body position approaches the center of the magnetic field of the static magnetic field magnet 10.

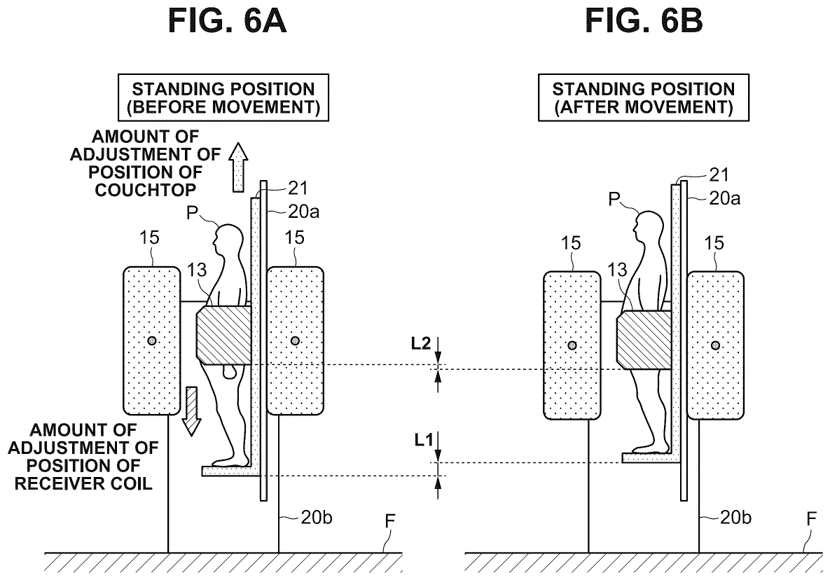

Here, FIG. 6A illustrates a state after the subject P has changed in body position from the supine position to the standing position and before the movement of the couchtop 21 and the receiver coil 13 in step ST8, which will be described below, is performed. FIG. 6B illustrates a state after the movement of the couchtop 21 and the receiver coil 13 in step ST8, which will be described below, has been performed from the standing position illustrated in FIG. 6A. The position of the examination target portion of the subject P relative to the static magnetic field magnet 10 changes before and after the change in body position from the supine position to the standing position. Therefore, the amount of adjustment L1 for the position of the couchtop 21 and the amount of adjustment L2 for the position of the receiver coil 13 are calculated so that the position of the examination target portion of subject P approaches to the center of the magnetic field and sufficient MR signal receiver sensitivity can be obtained.

In step ST8, the driving function F4 moves at least one of the couchtop 21 and the receiver coil 13 based on the amount of adjustment L1 for the position of the couchtop 21 and the amount of adjustment L2 for the position of the receiver coil 13. The driving function F4 may move at least one of the couchtop 21 and the receiver coil 13, in a case where the subject P is scanned in the second state, so that a difference between a position of the examination target portion of the subject P in the first state and a position of the examination target portion of the subject in the second state is reduced. The driving function F4 may move at least one of the couchtop 21 and the receiver coil 13 so that a first difference between a position of the center of the static magnetic field and the position of the examination target portion of the subject P in the first state is reduced in a case where the subject P is scanned in the first state, and may move the at least one of the couchtop 21 and the receiver coil 13 so that a second difference between the position of the center of the static magnetic field and the position of the examination target portion of the subject P in the second state is reduced in a case where the subject P is scanned in the second state.

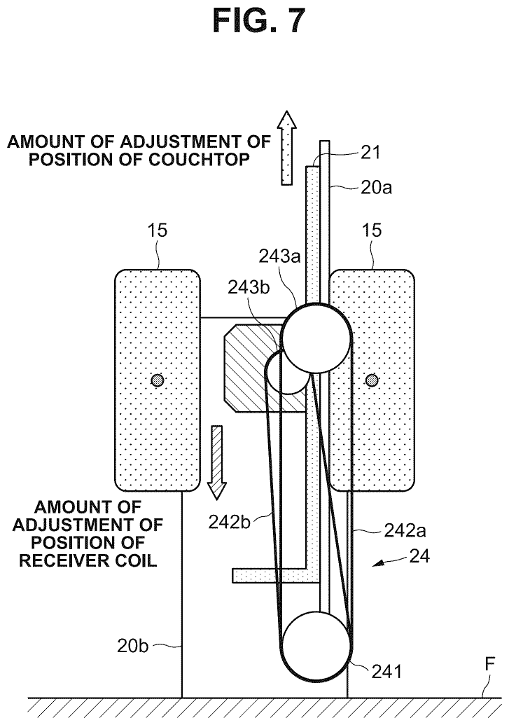

The driving function F4 moves at least one of the couchtop 21 and the receiver coil 13 along a longitudinal direction of the couchtop 21 (that is, the Z-axis direction). A description will be given of the movement of the couchtop 21 and the receiver coil 13 along the longitudinal direction of the couchtop 21 with reference to FIG. 7; however, the movement direction of the couchtop 21 and the receiver coil 13 is not limited. The driving function F4 may move at least one of the couchtop 21 and the receiver coil 13 along the short-side direction of the couchtop 21 (that is, the X-axis direction), or may move at least one of the couchtop 21 and the receiver coil 13 along the vertical direction of the couchtop 21 (that is, the Y-axis direction).

The gantry apparatus 100 includes an actuator 24. The actuator 24 includes an energy conversion mechanism 241 and a belt mechanism, and outputs power for moving at least one of the couchtop 21 and the receiver coil 13. The actuator 24 moves the couchtop 21 via a belt mechanism including a belt 242a and a movement mechanism 243a for the couchtop 21, such as a wheel, using the energy conversion mechanism 241 as a power source. The actuator 24 moves the receiver coil 13 via a belt mechanism including a belt 242b and a movement mechanism 243b for the receiver coil 13, such as a wheel, using the energy conversion mechanism 241 as a drive source.

The energy conversion mechanism 241 of the actuator 24 is, for example, a motor, and it is desirable that the energy conversion mechanism 241 be disposed outside the static magnetic field magnet 10. Disposing the energy conversion mechanism 241 outside the static magnetic field magnet 10 in this manner suppresses interaction with the static magnetic field. Additionally, it is desirable that the energy conversion mechanism 241 be powered off during image acquisition so as not to induce noise.

In the actuator 24, a common energy conversion mechanism 241 may be used for both the movement of the couchtop 21 and the movement of the receiver coil 13, or separate energy conversion mechanisms 241 may be used. In the actuator 24, an existing common energy conversion mechanism 241 for moving the couchtop 21 may be used for moving the receiver coil 13. The actuator 24 is not limited to a belt mechanism, and may be a ball screw mechanism.

It is desirable that wiring for transmitting and receiving MR signals be arranged in the gantry apparatus 100 so as to be kept at a predetermined distance or more from the center of the magnetic field of the static magnetic field magnet 10. Arranging the wiring for transmitting and receiving MR signals in this manner makes it possible to prevent or reduce adverse effects on the captured image. For example, the wiring for transmitting and receiving MR signals may be covered to avoid interaction with the static magnetic field and may be arranged on the back surface side of the couch main body 20.

In step ST9, an MR image in the standing position is collected by the MRI apparatus 1 through a main scan. The subject P on the couchtop 21 is scanned in the first state where the gantry apparatus 100 is located at the first position, which is the supine position in the first embodiment, before the subject P on the couchtop 21 is scanned in a second state where the gantry apparatus 100 is located at the second position, which is the standing position in the first embodiment.

In the MRI apparatus 1 according to the first embodiment, even after the change in body position of the subject P, the examination target portion of the subject P is positioned at the center of the magnetic field of the static magnetic field magnet 10 having high magnetic field homogeneity, so that an image of the examination target portion of the subject P is appropriately captured. Additionally, since MR signals from the examination target portion can be obtained with sufficient receiver sensitivity, an MR image with good image quality can be acquired in the imaging region used for diagnosis or the like. Furthermore, the user's effort required to move the couchtop 21 and the receiver coil 13 is reduced.

### (Modification of First Embodiment)

While the MRI apparatus 1 according to the first embodiment sets the gantry apparatus 100 so as to capture images of the subject P before and after a change in body position between a supine position and a standing position, an MRI apparatus 1 according to a modification of the first embodiment is different from the MRI apparatus 1 according to the first embodiment in setting the gantry apparatus 100 so as to capture images of the subject P before and after a change in body position between a supine position and a sitting position. That is, the MRI apparatus 1 according to the modification of the first embodiment can image the subject P before and after a change in body position between a supine position and a sitting position. The modification of the first embodiment can be interpreted by replacing “standing position” in the first embodiment with “sitting position”.

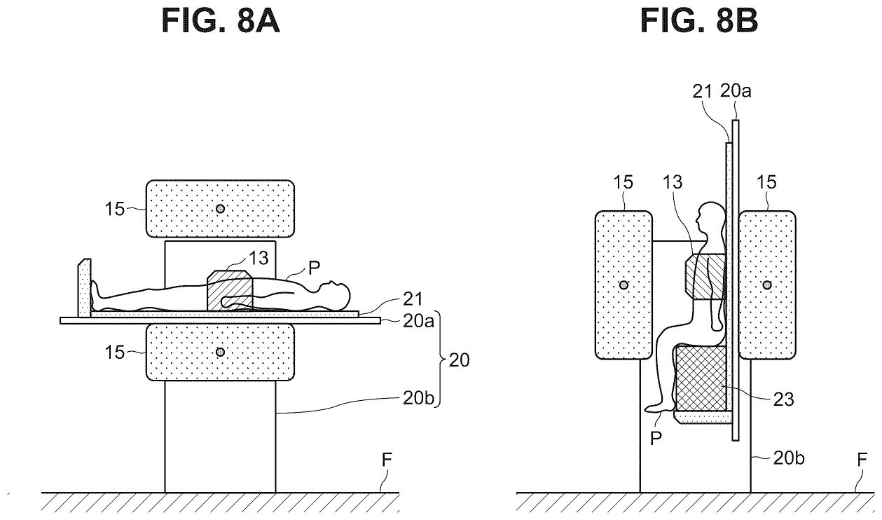

FIGS. 8A and 8B are diagrams illustrating a change in body position between a supine position and a sitting position. The following description will be given of a case where the MRI apparatus 1 sets the gantry apparatus 100 so as to image the subject P after the body position of the subject P is changed from the supine position to the sitting position; however, the MRI apparatus 1 may set the gantry apparatus 100 so as to image the subject P after the body position of the subject P is changed from the sitting position to the supine position.

In the modification of the first embodiment, the gantry apparatus 100 is further capable of stowing and unfolding a seat 23 provided in the couchtop 21. In the modification of the first embodiment, in step ST3 in FIG. 4 (in a case where the body position of the subject P is changed from the supine position to the sitting position), the MRI apparatus 1 sets the gantry apparatus 100 so as to image the subject P in the sitting position.

Specifically, the MRI apparatus 1 rotates the gantry apparatus 100 and holds the gantry apparatus 100 at a predetermined tilt angle while unfolding the seat 23 from the couchtop 21 (refer to FIG. 8B). In a case where the body position of the subject P is changed from the sitting position to the supine position, the MRI apparatus 1 rotates the gantry apparatus 100 and holds the gantry apparatus 100 at a predetermined tilt angle, while stowing the seat 23 into the couchtop 21 (refer to FIG. 8A).

### Second Embodiment

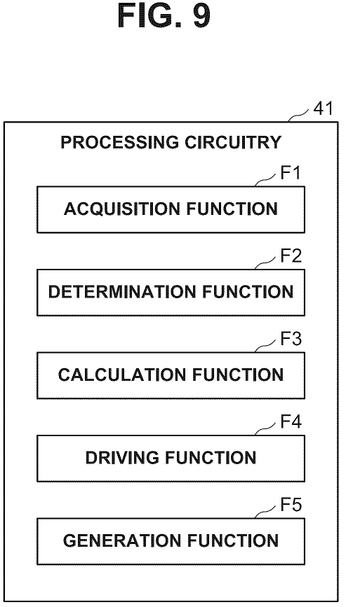

FIG. 9 is a block diagram illustrating an example of processing circuitry 41 of an MRI apparatus 1 according to a second embodiment. The second embodiment is different from the first embodiment in that the processing circuitry 41 further executes a generation function F5.

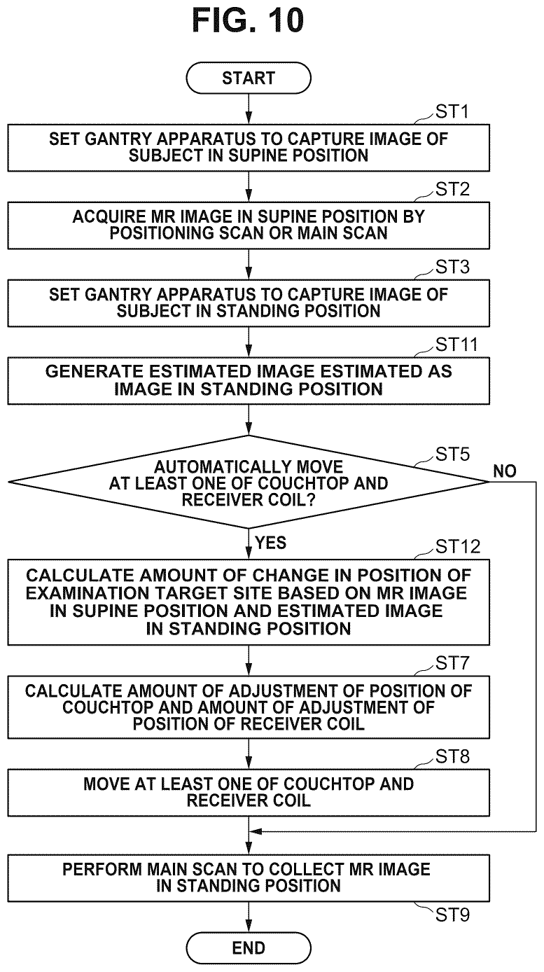

An example of an operation of the MRI apparatus 1 according to the second embodiment will be described with reference to a flowchart in FIG. 10. In the second embodiment, after step ST3, the processing proceeds to step ST11.

In step ST11, the generation function F5 generates an estimated image that is estimated as an image of the subject P after the change in body position, based on an MR image of the subject P before the change in body position, The estimated image may be generated by a generative AI. In the second embodiment, after step ST11, the processing proceeds to step ST5. After step ST5, the processing proceeds to step ST12.

In step ST12, the calculation function F3 calculates an amount of change between the position of the examination target portion of the subject P before the change in body position and the position of the examination target portion of the subject P after the change in body position, based on the MR image before the change in body position and the estimated image after the change in body position. Since step ST12 is different from step ST6 only in that the images used to calculate the amount of change are different, overlapping descriptions are omitted.

According to the MRI apparatus 1 according to the second embodiment, the similar effects to those obtained by the MRI apparatus 1 according to the first embodiment can be obtained, and since the scan in step ST4 in the first embodiment becomes unnecessary, the imaging time can be shortened.

### (Modification of Second Embodiment)

In calculation of the amount of change between the position of the examination target portion of the subject P before the change in body position and the position of the examination target portion of the subject P after the change in body position, it is possible to select whether to use the MR image in the first embodiment or the estimated image in the second embodiment as the image after the change in body position. For example, a screen for selecting the image after the change in body position may be output to the display 45, and information related to the selection of the image after the change in body position may be input by the user via the input interface 43.

### Third Embodiment

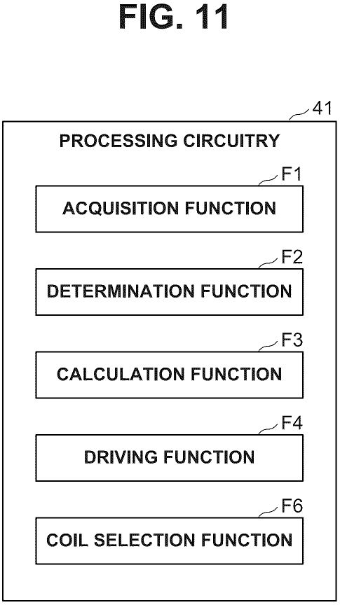

FIG. 11 is a block diagram illustrating an example of processing circuitry 41 of an MRI apparatus 1 according to a third embodiment. The third embodiment is directed to a case where the receiver coil 13 includes a plurality of element coils. The third embodiment is different from the first embodiment in that the processing circuitry 41 further executes a coil selection function F6. In the third embodiment, since the receiver coil 13 includes a plurality of element coils, the coil selection function F6 identifies the element coil that receives the MR signals.

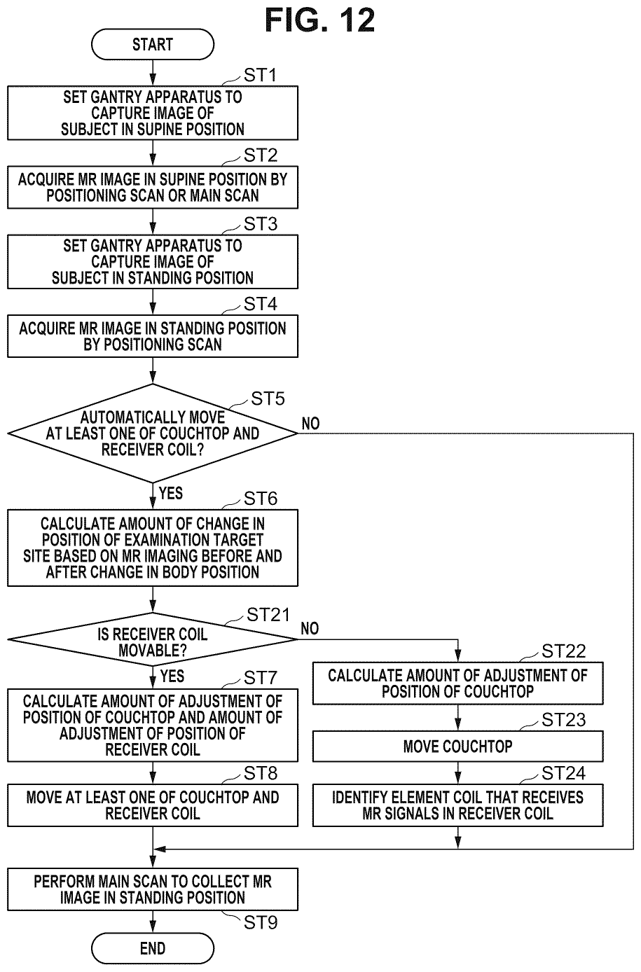

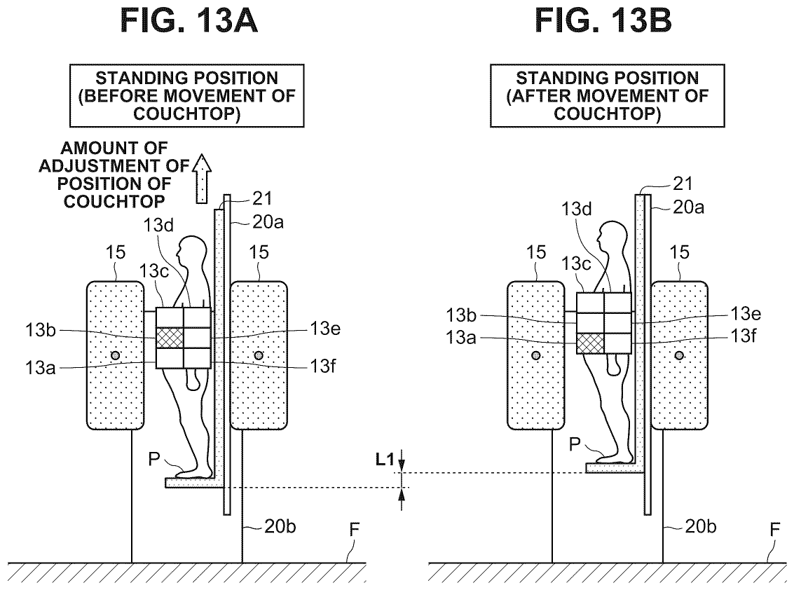

An example of an operation of the MRI apparatus 1 according to the third embodiment will be described with reference to a flowchart in FIG. 12 and FIGS. 13A and 13B. In the third embodiment, after step ST6, the processing proceeds to step ST21.

In step ST21, the coil selection function F6 determines whether the receiver coil 13 is movable. Whether the receiver coil 13 is movable may be predetermined according to the type of the receiver coil 13, or may be set by the user via the input interface 43. For example, in a case where the receiver coil 13 is a highly flexible type that is deformable and has a high degree of freedom in placement, such as a phased array coil or a so-called wearable type coil, the coil selection function F6 may determine that the receiver coil 13 is immovable.

In the third embodiment, in a case where the coil selection function F6 determines that the receiver coil 13 is movable (that is, YES in step ST21), the processing proceeds to step ST7. In contrast, in a case where the coil selection function F6 determines that the receiver coil 13 is immovable (that is, NO in step ST21), the processing proceeds to step ST22.

In step ST22, the calculation function F3 calculates the amount of adjustment L1 for the position of the couchtop 21 so that the position of the examination target portion after the change in body position approaches the center of the magnetic field of the static magnetic field magnet 10, based on the amount of change between the position of the examination target portion of the subject P before the change in body position and the position of the examination target portion of the subject P after the change in body position. In step ST22, the calculation function F3 may omit calculating the amount of adjustment L2 for the position of the receiver coil 13, or may calculate the amount of adjustment L2 for the position of the receiver coil 13 in the same manner as in step ST7.

In step ST23, the driving function F4 moves the couchtop 21 based on the amount of adjustment L1 for the position of the couchtop 21. In a case where the amount of adjustment L1 for the position of the couchtop 21 is zero, the couchtop 21 may not be moved.

In step ST24, the coil selection function F6 identifies the element coil for receiving MR signals among the plurality of element coils included in the receiver coil 13. There may be one or a plurality of element coils that receive MR signals. That is, a channel for receiving MR signals within the receiver coil 13 or a coil section composed of a plurality of element coils is identified. In the third embodiment, after step ST24, the processing proceeds to step ST9. Step ST24 may be performed before step ST23 or before step ST22.

The movement of the couchtop 21 and the identification of the element coil will be described with reference to FIGS. 13A and 13B. While FIGS. 13A and 13B illustrate a case where the receiver coil 13 includes six element coils 13a, 13b, 13c, 13d, 13e, and 13f, as an example, the number and arrangement of the plurality of element coils included in the receiver coil 13 are not limited to this example.

Here, FIG. 13A represents a state after the subject P has changed in body position from the supine position to the standing position and before the movement of the couchtop 21 in step ST23 is performed. The position of the examination target portion of the subject P changes before and after the change in body position from the supine position to the standing position. Therefore, the couchtop 21 is moved based on the amount of adjustment L1 for the position of the couchtop 21 calculated so that the position of the examination target portion of subject P approaches the center of the magnetic field. FIG. 13B represents a state after the movement of the couchtop 21 in step ST23 has been performed from the standing position illustrated in FIG. 13A.

In FIG. 13A, the element coil 13b is used for detection of MR signals in order to receive MR signals from the examination target portion of the subject P with sufficient reception sensitivity. However, due to the movement of the position of the examination target portion associated with the change in body position of the subject P and the movement of the couchtop 21, in a case where the element coil 13a, which is different from the element coil used in FIG. 13A, has a higher reception sensitivity, as illustrated in FIG. 13B, the element coil 13a is used for detection of MR signals. An element coil used for detection of MR signals may be changed according to the change in position of the examination target portion without moving the receiver coil 13.

According to the MRI apparatus 1 according to the third embodiment, the effect similar effects to those obtained by the MRI apparatus 1 according to the first embodiment can be obtained even in a case where an immovable receiver coil 13 is used.

According to the MRI apparatus according to at least one of the above-mentioned embodiments, it is possible to appropriately capture images of the examination target portion of the subject after the change in body position.

In the above embodiments, the term “processor” refers to, for example, circuitry such as a dedicated or general-purpose Central Processing Unit (CPU), Graphics Processing Unit (GPU), or an Application Specific Integrated Circuit (ASIC), as well as programmable logic devices (for example, a Simple Programmable Logic Device (SPLD), a Complex Programmable Logic Device (CPLD), and a Field Programmable Gate Array (FPGA)).

In a case where the processor is, for example, a CPU, the processor implements various functions by reading and executing a program stored in the memory circuitry. In a case where the processor is, for example, an ASIC, instead of storing the program in the memory circuitry, the functions corresponding to the program are directly incorporated into the processor as logic circuitry. In this case, the processor implements various functions through hardware processing that reads and executes the program embedded in the circuitry. Alternatively, the processor may implement various functions by combining software processing and hardware processing.

In the above embodiments, an example has been described in which a single processor of the processing circuitry implements each function. However, the processing circuitry may be configured by combining a plurality of independent processors, and each processor may implement each function. In addition, in a case where a plurality of processors is provided, the storage circuitry that stores the program may be provided individually for each processor, or a single storage circuit may collectively store programs corresponding to the functions of all the processors.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a gantry apparatus including a static magnetic field magnet configured to generate a static magnetic field and a couchtop on which a subject to be scanned is placed;
a supporting portion configured to rotatably support the gantry apparatus relative to the supporting portion between a first position and a second position, the subject on the couchtop being scanned in a first state where the gantry apparatus is located at the first position before the subject on the couchtop is scanned in a second state where the gantry apparatus is located at the second position;
a receiver coil configured to detect a magnetic resonance (MR) signal from the subject; and
a moving controller configured to, in a case where the subject is scanned in the second state, move at least one of the couchtop and the receiver coil in a longitudinal direction of the couchtop so that a difference between a position of an examination target portion of the subject in the first state and a position of the examination target portion of the subject in the second state is reduced.

2. The magnetic resonance imaging apparatus according to claim 1, wherein a posture of the subject in the first state is a supine posture and a posture of the subject in the second state is a standing posture.

3. The magnetic resonance imaging apparatus according to claim 1, wherein a posture of the subject in the first state is a supine posture and a posture of the subject in the second state is a sitting posture.

4. The magnetic resonance imaging apparatus according to claim 1, further comprising a processing circuitry configured to calculate the difference based on a first MR image obtained by scanning the subject in the first state and a second MR image obtained by scanning the subject in the second state.

5. The magnetic resonance imaging apparatus according to claim 1, further comprising a processing circuitry configured to calculate the difference based on artificial intelligence (AI).

6. A magnetic resonance imaging apparatus comprising:
a gantry apparatus including a static magnetic field magnet configured to generate a static magnetic field and a couchtop on which a subject to be scanned is placed;
a supporting portion configured to rotatably support the gantry apparatus relative to the supporting portion between a first position and a second position, the subject on the couchtop being scanned in a first state where the gantry apparatus is located at the first position before the subject on the couchtop is scanned in a second state where the gantry apparatus is located at the second position;
a receiver coil configured to detect a magnetic resonance (MR) signal from the subject; and
a moving controller configured to move at least one of the couchtop and the receiver coil in a longitudinal direction of the couchtop so that a first difference between a position of a center of the static magnetic field and the position of the examination target portion of the subject in the first state is reduced in a case where the subject is scanned in the first state, and configured to move the at least one of the couchtop and the receiver coil in the longitudinal direction so that a second difference between the position of the center of the static magnetic field and the position of the examination target portion of the subject in the second state is reduced in a case where the subject is scanned in the second state.

7. The magnetic resonance imaging apparatus according to claim 6, wherein a posture of the subject in the first state is a supine posture and a posture of the subject in the second state is a standing posture.

8. The magnetic resonance imaging apparatus according to claim 6, wherein a posture of the subject in the first state is a supine posture and a posture of the subject in the second state is a sitting posture.

9. The magnetic resonance imaging apparatus according to claim 6, further comprising a processing circuitry configured to determine the position of the examination target portion of the subject in the first state based on a first MR image obtained by scanning the subject in the first state, and determine the position of the examination target portion of the subject in the second state based on a second MR image obtained by scanning the subject in the second state.

10. The magnetic resonance imaging apparatus according to claim 6, further comprising a processing circuitry configured to determine the position of the examination target portion of the subject in the second state based on artificial intelligence (AI).
